(19) United States
(12) Patent Application Publication
(10) Pub. No.: US 2011/0129102 A1
(43) Pub. Date: Jun. 2, 2011

(54) METHOD AND APPARATUS FOR CONTROLLING SOUND VOLUME IN MOBILE COMMUNICATION TERMINAL

(75) Inventors: Jin SAGONG, Suwon-si (KR); Hark-Sang KIM, Seoul (KR); Sang-Ryul PARK, Hwaseong-si (KR); Ju-Gab LEE, Hwaseong-si (KR); Youn-Hyoung KIM, Suwon-si (KR)

(73) Assignee: SAMSUNG ELECTRONICS CO. LTD., Suwon-si (KR)

(21) Appl. No.: 12/957,818

(22) Filed: Dec. 1, 2010

(30) Foreign Application Priority Data
Dec. 1, 2009 (KR) 10-2009-0117685

(51) Int. Cl. H03G 3/00

(52) U.S. Cl. 381/104

(57) ABSTRACT

A method and an apparatus for controlling a sound volume in a mobile communication terminal are provided. The method of controlling the sound volume in the mobile communication terminal includes connecting a call to a counterpart mobile communication terminal, determining an output volume according to an identifier of the counterpart mobile communication terminal using pre-stored volume information per identifier, and adjusting and outputting a volume of a voice signal received from the counterpart mobile communication terminal according to the determined output volume.

### PRIORITY

The present application claims the benefit under 35 U.S.C. §119(a) of a Korean patent application filed in the Korean Intellectual Property Office on Dec. 1, 2009, and assigned Serial No. 2009-0117685, the entire disclosure of which is hereby incorporated by reference.

### BACKGROUND OF THE INVENTION

1. Field of the Invention

The present invention relates to a method and an apparatus for controlling a sound volume in a mobile communication terminal. More particularly, the present invention relates to a method and an apparatus for controlling a receive volume according to a phone number.

2. Description of the Related Art

Mobile communication terminals, which allow users to communicate and exchange messages with other users on the move and which provide various services such as schedule management and games, have become a necessity for many of the users.

The mobile communication terminal users talk over the phone according to their individual habits. For example, a user might speak into a microphone close to his/her mouth, speak into the microphone away from the mouth, talk with a loud voice, or talk with a small voice. Since the users speak over the phone according to their individual habits, a sound volume of people on the phone can vary according to a particular user.

However, the mobile communication terminal outputs a sound signal received from another mobile communication terminal in a regular volume. Disadvantageously, the user of the mobile communication terminal needs to personally listen to the sound signal received from the other mobile communication terminal and manually increase or decrease the receive volume according to his/her preference or situation.

### SUMMARY OF THE INVENTION

An aspect of the present invention is to address at least the above-mentioned problems and/or disadvantages and to provide at least the advantages below. Accordingly, an aspect of the present invention is to provide a method and an apparatus for controlling a receive volume in a mobile communication terminal.

Another aspect of the present invention is to provide a method and an apparatus for controlling a receive volume, according to a phone number of another mobile communication terminal, in a mobile communication terminal.

Yet another aspect of the present invention is to provide a method and an apparatus for storing receive volume control information according to a phone number in a mobile communication terminal.

According to one aspect of the present invention, a method for controlling a sound volume in a mobile communication terminal is provided. The method includes connecting a call to a counterpart mobile communication terminal, determining an output volume according to a phone number of the counterpart mobile communication terminal using pre-stored volume information per phone number, and adjusting and outputting a volume of a voice signal received from the counterpart mobile communication terminal according to the determined output volume.

According to another aspect of the present invention, an apparatus for controlling a sound volume in a mobile communication terminal is provided. The apparatus includes a storage unit for storing volume information per phone number, a controller for, when a call is connected to a counterpart mobile communication terminal, determining an output volume according to a phone number of the counterpart mobile communication terminal using the volume information per phone number, and a voice processor for adjusting and outputting a volume of a voice signal received from the counterpart mobile communication terminal according to the output volume.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 is a block diagram of a mobile communication terminal according to an exemplary embodiment of the present invention;

FIG. 2 is a diagram of volume information stored per phone number in the mobile communication terminal according to an exemplary embodiment of the present invention; and

FIG. 3 is a flowchart of a volume control method in the mobile communication terminal according to an exemplary embodiment of the present invention.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

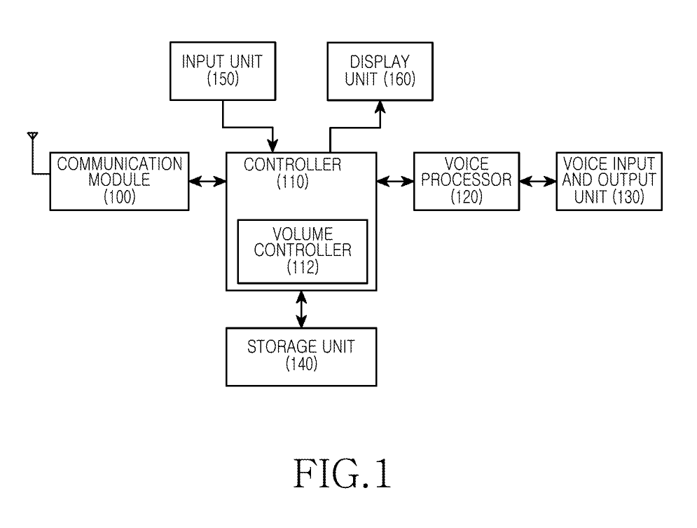

FIGS. 1 to 3, discussed below, and the various exemplary embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly state otherwise. A set is defined as a non-empty set including at least one element.

Exemplary embodiments of the present invention provide a technique for storing receive volume control information per phone number in a mobile communication terminal, and controlling the receive volume according to a phone number of the other mobile communication terminal when a call is made.

FIG. 1 is a block diagram of a mobile communication terminal according to an exemplary embodiment of the present invention.

Referring to FIG. 1, the mobile communication terminal includes a communication module 100, a controller 110, a voice processor 120, a voice input and output unit 130, a storage unit 140, an input unit 150, and a display unit 160. The controller 110 includes a volume controller 112.

The communication module 100 processes signals transmitted and received over an antenna under the control of the controller 110. In more detail, the communication module 100 up-converts a baseband signal output from the controller 110 into a radio frequency signal and sends the radio frequency signal over the antenna, down-converts a radio frequency signal received via the antenna into a baseband signal and outputs the baseband signal to the controller 110. More particularly, the communication module 100 provides a voice signal received from another mobile communication terminal to the controller 110.

The controller 110 controls and processes operations of the mobile communication terminal. The controller 110, including the volume controller 112, controls and processes a function for controlling the volume of the output voice signal, according to a phone number of the other mobile communication terminal, during the phone call.

More specifically, when the phone call is made, the volume controller 112 checks the phone number of the other mobile communication terminal and then determines whether receive volume control information (hereafter, referred to as volume information) of the phone number is pre-stored. When the volume information is pre-stored, the volume controller 112 adjusts the output volume of the voice signal received from the other mobile communication terminal using the pre-stored volume information. When the volume information is not pre-stored, the volume controller 112 controls to adjust the output volume of the voice signal received from the other mobile communication terminal according to basic volume information. Herein, the volume information includes at least one of a speaker volume, a receiver volume, an earphone volume, and a Bluetooth earphone volume. More than one type of volume information may be included for the same phone number, and the volume information for different types may be different. The volume controller 112 provides the voice processor 120 with the volume corresponding to the current voice output path of the mobile communication terminal in the pre-stored volume information.

When a user's manipulation changes the volume in the communication with the other mobile communication terminal, the volume controller 112 controls to store and update information relating to the changed volume as volume information relating to the phone number of the mobile communication terminal.

The voice processor 120 is referred to as a Coder-Decoder (CODEC) and processes the input and the output of the voice signal via the voice input and output unit 130. For example, the voice processor 120 converts a digital voice signal fed from the controller 110 into an analog voice signal and sends the analog voice signal through the voice input and output unit 130. The voice processor 120 converts the voice signal fed from the voice input and output unit 130 into a digital voice signal and provides the digital voice signal to the controller 110. In particular, under the control of the volume controller 112 of the controller 110, the voice processor 120 adjusts the volume of the voice signal and then provides the adjusted voice signal to the voice input and output unit 130. For example, the voice processor 120 receives the voice signal and the volume information relating to the voice signal from the volume controller 112, and amplifies the voice signal according to the volume information.

The voice input and output unit 130 outputs the voice fed from the voice processor 120, and receives and forwards the user's voice to the voice processor 120. The voice input and output unit 130 may include at least one of a speaker, a receiver, earphones, and a microphone. Herein, the receiver represents a speaker for lower-power voice communication.

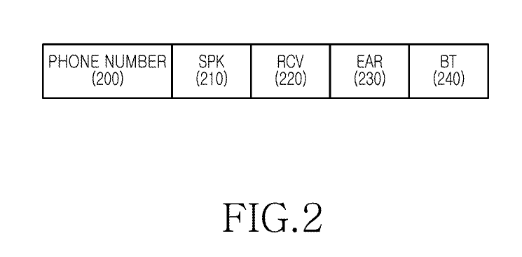

The storage unit 140 stores programs and data for the operations of the mobile communication terminal. Under the control of the volume controller 112, the storage unit 140 stores the volume information per phone number. For instance, referring to FIG. 2, the storage unit 140 maps and stores volume information of the speaker output SPK 210, volume information of the receiver output RCV 220, volume information of the earphone output EAR 230, and volume information of the Bluetooth earphone output BT 240 information to the phone number 200. In so doing, the storage unit 140 may store the volume information per phone number only for the phone numbers stored to a phonebook, or may do so for every phone number contacted. For example, the storage unit 140 may store the volume information per phone number to the phonebook, and also to an extra space for the phone numbers in a phone number recording region.

The input unit 150 includes at least one input key or touch sensor, and provides data corresponding to the key or the touch of the user to the controller 110. In particular, the input unit 150 receives the key input for changing the output volume of the voice signal received from the other mobile communication terminal, and provides the received key input to the controller 110.

The display unit 160 displays state information, a limited number of numerals and characters, videos, and still images generated in the operations of the mobile communication terminal.

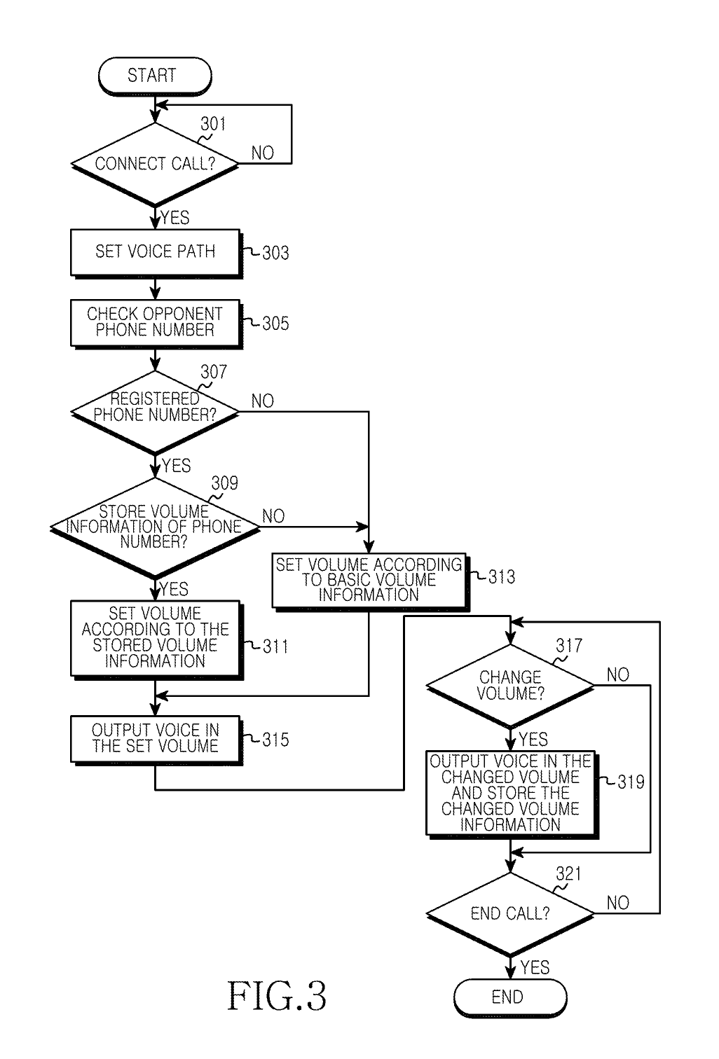

FIG. 3 is a flowchart of a volume control method in the mobile communication terminal according to an exemplary embodiment of the present invention.

Referring to FIG. 3, when the phone call is connected to the other mobile communication terminal in step 301, the mobile communication terminal sets the output path of the voice signal in step 303. For instance, the mobile communication terminal determines which one of the speaker, the receiver, the earphones, and the Bluetooth earphones outputs the voice signal.

Next, the mobile communication terminal checks the phone number of the other mobile communication terminal in step 305 and examines whether the phone number is pre-registered to the mobile communication terminal in step 307. For example, the mobile communication terminal examines whether the phone number is pre-registered to the phonebook, or whether the phone number, which is not registered to the phonebook, is registered as a previous contact phone number.

When the phone number is pre-registered to the mobile communication terminal, the mobile communication terminal determines whether the volume information of the phone number is stored in step 309. For example, for the phone number 200, the mobile communication terminal determines whether at least one of the volume information of the speaker output SPK 210, the volume information of the receiver output RCV 220, the volume information of the earphone output EAR 230, and the volume information of the Bluetooth earphone output BT 240 information is stored as shown in FIG. 2.

If it is determined in step 309 that the volume information for the phone number is not stored, the mobile communication terminal controls and sets the volume of the voice signal received from the other mobile communication terminal according to the preset basic volume information in step 313, and then proceeds to step 315.

In contrast, if it is determined in step 309 that the volume information for the phone number is stored, the mobile communication terminal controls and sets the volume of the voice signal received from the other mobile communication terminal according to the stored volume information in step 311, and then proceeds to step 315. Herein, the mobile communication terminal determines the volume information corresponding to the voice output path set in step 303 in the volume information, and controls and sets the volume of the voice signal received from the other mobile communication terminal according to the volume information corresponding to the voice output path.

Next, the mobile communication terminal outputs the voice amplified or adjusted to the set volume in step 315, and determines whether the volume is changed by the user's key manipulation in step 317. For example, the mobile communication terminal may determine whether one of two side keys for increasing and decreasing the volume is input.

If it is determined that the volume is not changed by the user's key manipulation, the mobile communication terminal proceeds to step 321. If it is determined that the volume is changed by the user's key manipulation, the mobile communication terminal outputs the voice in the changed volume and stores the changed volume information in step 319. Herein, the mobile communication terminal stores and updates the set voice output path and the changed volume information in relation to the phone number of the other mobile communication terminal. For example, when the key for the volume increase of the side keys is input once, the mobile communication terminal may amplify the volume of the output voice by one level and store the volume information indicating that the volume for that phone number is set to one greater level.

In step 321, the mobile communication terminal checks whether the call with the other mobile communication terminal ends. If it is determined that the call does not end, the mobile communication terminal goes back to step 317. If it is determined that the call ends, the mobile communication terminal finishes this process.

As set forth above, the mobile communication terminal stores the information for controlling the receive volume per phone number, and controls the receive volume according to the phone number of the counterpart mobile communication terminal in the phone call. Therefore, there is no need to adjust the volume in every phone call in accordance with the voice volume of the counterpart user.

While the invention has been shown and described with reference to certain exemplary embodiments thereof, it will be understood by those skilled in the art that various changes in form and details may be made therein without departing from the spirit and scope of the invention as defined by the appended claims and their equivalents

What is claimed is:

1. A method for controlling a sound volume in a mobile communication terminal, the method comprising:
connecting a call to a counterpart mobile communication terminal;
determining an output volume according to an identifier of the counterpart mobile communication terminal using pre-stored volume information according to the identifier; and
adjusting and outputting a volume of a voice signal received from the counterpart mobile communication terminal according to the determined output volume.

2. The method of claim 1, wherein the volume information comprises at least one of a speaker output volume, a receiver output volume, an earphone output volume, and a Bluetooth earphone output volume.

3. The method of claim 2, wherein the determining of the output volume comprises:
determining an output path for outputting the voice signal received from the counterpart mobile communication terminal; and
determining a volume corresponding to the output path in the volume information corresponding to the identifier of the counterpart mobile communication terminal, as the output volume.

4. The method of claim 1, further comprising:
if it is determined that there is no pre-stored volume information corresponding to the identifier of the counterpart mobile communication terminal, adjusting and outputting the volume of the received voice signal in a preset basic volume.

5. The method of claim 1, further comprising:
determining whether a user changes the volume when the voice signal is output; and
if it is determined that the volume is changed, mapping and storing information relating to the changed volume to the identifier.

6. The method of claim 5, further comprising outputting the volume of the voice signal according to the changed volume.

7. The method of claim 5, further comprising mapping and storing the changed volume information to a phone book function according to the identifier.

8. The method of claim 1, wherein the identifier comprises a phone number.

9. An apparatus for controlling a sound volume in a mobile communication terminal, the apparatus comprising:
a storage unit for storing volume information per identifier;
a controller for, when a call is connected to a counterpart mobile communication terminal, determining an output volume according to an identifier of the counterpart mobile communication terminal using the volume information per identifier; and
a voice processor for adjusting and outputting a volume of a voice signal received from the counterpart mobile communication terminal according to the output volume.

10. The apparatus of claim 9, wherein the volume information comprises at least one of a speaker output volume, a receiver output volume, an earphone output volume, and a Bluetooth earphone output volume.

11. The apparatus of claim 10, wherein the controller determines a volume corresponding to an output path of the received voice signal in the volume information corresponding to the identifier of the counterpart mobile communication terminal, as the output volume.

12. The apparatus of claim 9, wherein, if it is determined that there is no volume information corresponding to the identifier of the counterpart mobile communication terminal stored in the storage unit, the controller determines a preset basic volume as the output volume.

13. The apparatus of claim 9, wherein the controller determines whether a user changes the volume when the voice signal is output, and
if it is determined that the volume is changed, the controller controls to map and store information relating to the changed volume according to the identifier.

14. The apparatus of claim 13, wherein the voice processor outputs the volume of the voice signal according to the changed volume.

15. The method of claim 13, wherein the changed volume information is mapped and stored to a phone book function according to the identifier.

16. The method of claim 9, wherein the identifier comprises a phone number.
